(19) United States
(12) Patent Application Publication
(10) Pub. No.: US 2005/0153571 A1
(43) Pub. Date: Jul. 14, 2005

(54) Nitridation of high-k dielectric films

(76) Inventor: Yoshihide Senzaki, Austin, TX (US)

Correspondence Address: DORSEY & WHITNEY LLP;INTELLECTUAL PROPERTY DEPARTMENT, 4 EMBARCADERO CENTER, SUITE 3400, SAN FRANCISCO, CA, 94111, US

(21) Appl. No.: 10/919,666

(22) Filed: Aug. 16, 2004

Related U.S. Application Data
(60) Provisional application No. 60/520,964, filed on Nov. 17, 2003.

(51) Int. Cl. H01L 21/8242; H01L 21/3205; H01L 21/31; H01L 21/4763; H01L 21/469

(52) U.S. Cl. 438/778; 438/785; 438/591

(57) ABSTRACT

The present invention promotes incorporation of nitrogen (e.g., nitridation) into high-k dielectric films using a low temperature process. Further, the present invention provides an in-situ method; that is formation of the high-k dielectric film and nitridation of the film are carried out in the same process chamber during deposition of the film, as opposed to the conventional post processing techniques. In another aspect, a method for depositing a multi-layer material for use as a gate dielectric layer in semiconductor devices is provided.

### RELATED APPLICATIONS

The present invention claims the benefit of, and priority to, U.S. Provisional Patent Application Ser. No. 60/520,964, filed on Nov. 17, 2003, entitled: ALD of HiSiON with Controlled Thickness and Compositional Gradient, the entire disclosure of which is hereby incorporated by reference. The present invention is related to pending U.S. patent application Ser. No. 10/869,770 filed on Jun. 15, 2004, which is a CIP application of U.S. patent application Ser. No. 10/829,781 filed on Apr. 21, 2204, the disclosures of both of which are hereby incorporated by reference in their entirety.

### FIELD OF THE INVENTION

The present invention relates generally to formation of dielectric films having high dielectric constant (high-k) for use in semiconductor substrates and wafers. More specifically, the present invention relates to incorporation of nitrogen into high-k dielectric films at low temperatures.

### BACKGROUND OF THE INVENTION

Advances in semiconductor devices require that critical dimensions of such devices continue to shrink. These critical dimensions comprise the line widths and spacing of structures as well as the thickness of critical layers such as the gate dielectric layer. Traditionally, silicon dioxide (SiO₂) has been used as the gate dielectric layer of choice. It has desirable properties of low leakage current, good uniformity, high mobility (a measure of transistor speed), and is thermally stable. The thickness requirement of the gate dielectric layer is approaching equivalent oxide thickness (EOT) below 10 Å. At this thickness, electrons can “tunnel” through the SiO₂ gate dielectric layer leading to excessively high leakage currents when the device is in the “off” condition. To overcome this problem, alternative dielectric materials that have higher electrical permittivity than SiO₂ (dielectric constant k=3.9) are being investigated. These materials are known as “high-k” materials in the literature (typically defined as having a dielectric content k>10). The use of these materials would allow the physical thickness of the gate dielectric layer to be increased to greater than 20 Å and still meet the electrical requirements of the industry for the gate dielectric layer.

High-k materials being investigated to replace SiO₂ as a gate dielectric layer are generally compounds of metal-oxygen or metal-silicon-oxygen. The use of pure metal-oxygen compounds as the gate dielectric layer suffers from several issues that include low mobility (slow transistor speed), reactivity with the underlying silicon substrate, and poor diffusion blocking properties with respect to boron. The metal-silicon-oxygen compounds are less reactive with the underlying silicon substrate and have better boron diffusion blocking properties, but suffer from lower k-values and therefore, require the deposition of thinner films. It is clear that the development of a method for depositing a gate dielectric layer that solves the leakage problems of the SiO₂ gate dielectric layer while maintaining the desirable properties and transistor performance specifications would be a desirable invention.

Another problem faced in the industry is diffusion of dopants and degradation of the dielectric films during processing. To address this problem, nitrogen is frequently incorporated into the dielectric to yield oxynitrides. Oxynitrides, such as silicon oxynitride, suppress boron drift from the gate electrode and reduce the generation of defects in the dielectric, but thermally grown oxynitrides have a dielectric constant only slightly higher than silicon dioxide. In addition, unlike the ordered interfacial network that forms between silicon and silicon dioxides, the interface between the silicon substrate and the nitride dielectric gives rise to charge trapping and hysteresis, both of which cause a shift in the threshold voltage and lower electron mobility. Therefore, it would be desirable to provide a system and method for depositing nitrogen selectively near or above the silicon substrate—dielectric interface to deter boron diffusion. It also would be desirable to provide a system and method for deterring boron diffusion without placing a burden on the equivalent oxide thickness (EOT) of the dielectric and quality of the interface between the silicon and the nitride dielectric, leading, for example to higher trap densities.

Two common methods for generating oxynitrides are thermal oxynitridation and remote plasma nitridation; however, there are several drawbacks associated with both techniques. With respect to thermal oxynitridation, high temperatures (greater than 700 C) are required to facilitate nitridation. As such, the effective cost and time for manufacturing are high. In addition, the higher temperatures may crystallize the dielectric creating grain boundaries that may induce current leakage. With respect to remote plasma nitridation, the uniformity of the nitride layer across the wafer is difficult to control Plasma process generally suffers recombination of atomic nitrogen to N₂. In addition, the use of high energy atoms may damages the dielectric film creating structural fissures, faults and other imperfections. Furthermore, the heat generated from the reaction between the high energy nitrogen atoms and the film may cause the dielectric layer to crystallize creating interfacial mismatches and structural defects and inconsistencies. Accordingly, further developments are needed.

### BRIEF SUMMARY OF THE INVENTION

The present invention promotes incorporation of nitrogen (e.g., nitridation) into high-k dielectric films using a low temperature process. Further, the present invention provides an in-situ method; that is formation of the high-k dielectric film and nitridation of the film are carried out in the same process chamber during deposition of the film, as opposed to the conventional post processing techniques.

In one aspect of the present invention provides a method of incorporating nitrogen into a high-k dielectric film by employing precursors that contain a nitridation reactant into a process chamber and carrying out atomic layer deposition (ALD) at relatively low temperatures, such as at temperatures of approximately 500° C. or less, typically in the range of approximately 25° C. to 500° C., and more usually at temperatures in the range of approximately 100° C. to 400° C. Suitable nitridation agents include ammonia, deuterated ammonia, ¹⁵N-ammonia, amines or amides, hydrazines, alkyl hydrazines, nitrogen gas, nitric oxide, nitrous oxide, nitrogen radicals, N-oxides, ND₃, and mixtures thereof. In one embodiment, the metal nitride films are oxidized by post deposition anneal in an oxygen containing source wherein oxygen oxidizes the metal-nitride film to form a high-k dielectric film on the surface of the substrate.

In another embodiment the present invention provides a method of forming a high-k dielectric film on one or more substrates in a process chamber, comprising the steps of: conducting one or more atomic layer deposition cycles, and each cycle carried out at a temperature of approximately 500° C. or less and comprises the steps of (a) conveying a metal containing precursor to the process chamber to form one or more layers of metal atoms on the surface of the substrate; (b) removing excess metal containing precursor from the process chamber; (c) conveying a nitrogen containing precursor to the process chamber wherein nitrogen interacts with the one or more layers of metal atoms to form a metal-nitrogen film on the substrate; and (d) removing excess nitrogen containing precursor from the process chamber. Then the metal-nitrogen film is oxidized to form a high-k dielectric film on the surface of the substrate.

In another embodiment of the present invention two distinct precursors are “co-injected” or conveyed together during the atomic layer deposition cycles. For example, a metal containing precursor and a silicon containing precursor are conveyed together to the process chamber to form a layer or layers of metal and silicon atoms on the surface of the substrate.

In another aspect, the present invention provides a method for deposition of a multi-layer film for use as the gate dielectric in a semiconductor device. The method provides a metal-silicon-oxygen layer deposited directly on the silicon substrate where the concentration of silicon is greater than the concentration of metal so that the desired properties of high mobility and a stable interface are preserved. The method provides a second layer, deposited in-situ with the first layer, which is comprised of a metal-oxygen material, or a metal-silicon-oxygen material, where the silicon concentration is less than the metal concentration such that a dielectric layer with the highest possible “k-value” is formed to promote desired dielectric properties of the layer, such as low leakage current.

The method further provides a third layer, deposited in-situ with the first two layers, which is comprised of a metal-oxygen material or a metal-silicon-oxygen material which is then reacted with a nitrogen precursor to incorporate nitrogen into the third layer. This serves to promote properties of the material to minimize the diffusion of boron through the multi-layer dielectric stack, and also increases crystallization temperature to suppress electrical leakage induced through grain boundaries of the dielectric layers. Additionally, the nitrided metal nitride or metal-silicon-nitride third layer may react with an oxygen source to form metal oxynitride or metal-silicon-oxynitride. In this embodiment, metal oxynitride (M-O—N) or metal-silicon-oxynitride (M-Si—O—N) serves to promote properties of the material to minimize the diffusion of boron through the multi-layer dielectric stack, and also increases crystallization temperature to suppress electrical leakage induced through grain boundaries of the dielectric layers. The reaction of metal nitride or metal silicon oxynitride with the oxygen source can be facilitated using a variety of energy means comprising any one or a combination of thermal, direct plasma, remote plasma, downstream plasma, or ultraviolet photons. The entire multi-layer material can be deposited sequentially, in-situ in the same process chamber.

### BRIEF DESCRIPTION OF THE DRAWINGS

The present invention is further described upon reading the following detailed description of the invention and upon reference to the following drawings, in which:

FIG. 1 is a flow chart illustrating one embodiment of the method of the present invention.

FIG. 2 is a flow chart illustrating another embodiment of the method of the present invention.

FIG. 3 is a schematic diagram showing a cross-section of the multi-layer gate dielectric material according to one embodiment of the present invention.

FIG. 4 is a graph showing x-ray photo electron spectroscopy (XPS) spectra illustrating nitrogen content present in HfSiOx films formed by method of the prior art of high temperature (800° C.) post deposition anneal in NH₃.

FIG. 5 depicts SIMS depth profiles illustrating nitrogen concentration as a function of film depth for high-k dielectric films formed according to various embodiments of the present invention.

FIG. 6 depicts SIMS depth profiles illustrating nitrogen concentration as a function of film depth for high-k dielectric films formed according to other various embodiments of the present invention.

FIG. 7 is a graph showing atomic concentration of various constituents as a function of sputter depth for post deposition annealed HfSiN films with O₃ according to one embodiment of the present invention.

FIGS. 8A and 8B illustrate electrical performance of capacitance and leakage current density, respectively, as a function of bias voltage for films formed according to various embodiments of the present invention.

### DETAILED DESCRIPTION OF THE INVENTION

The method of the present invention promotes incorporation of nitrogen (e.g., nitridation) into high-k dielectric films using a low temperature process. Further, the present invention allows for in-situ processing, that is formation of the high-k dielectric film and nitridation of the film are carried out in the same process chamber during deposition of the film, as opposed to the conventional techniques, which carry out nitridation of the film in post processing steps.

In one aspect of the present invention, a method is provided for forming a nitrided metal oxide film by atomic layer deposition (ALD) where nitrogen is incorporated into the film during deposition. In general, an illustrative embodiment the present invention provides a method of incorporating nitrogen into high-k dielectric films by providing precursors or reactants that contain a nitridation reactant into a process chamber and carrying out atomic layer deposition (ALD) at relatively low temperatures, such as at temperatures of approximately 500° C. or less, typically in the range of approximately 25° C. to 500° C., and more usually at temperatures in the range of approximately 100° C. to 400° C.

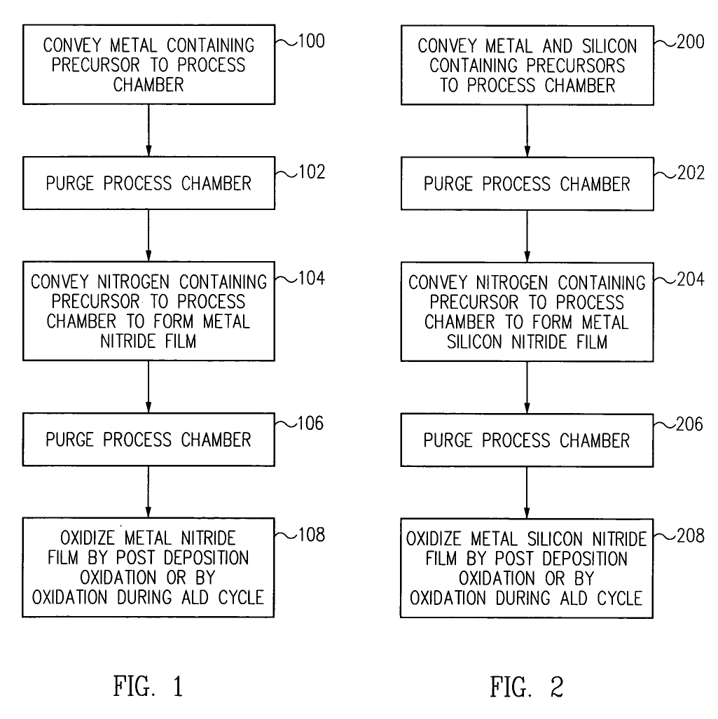

To form nitrogen containing high-k dielectric film on a substrate, referring to FIG. 1, a metal containing precursor gas is conveyed as a pulse at step 100 to a process chamber housing one or more semiconductor substrates. The metal containing precursor is chemisorbed on the surface of the one or more substrates according to known atomic layer deposition principles and forms one or more layers of metal atoms on the surface of the substrate. Any process chamber configured to carry out ALD processes may be used, and the process chamber may be configured as a single wafer chamber or as a batch chamber adapted to process a plurality of wafers. The method of the present invention is not limited to any particular type of process chamber. One example of a suitable batch process chamber is described in published PCT Patent Application Serial no. PCT/US03/21575, the disclosure of which is hereby incorporated by reference in its entirety.

The process chamber is purged at step 102 to remove excess precursor. Next, a nitrogen containing precursor gas is conveyed to the process chamber as a pulse at step 104. Nitrogen is chemisorbed on the surface of the substrate and reacts with the layer of metal atoms to form a metal-nitrogen film or layer on the surface of the substrate. The process chamber is then purged at step 106 to remove any remaining nitrogen containing precursors. Purging of the process chamber may be accomplished by pure evacuation, or by flowing an inert gas through the process chamber, or by a combination of both.

In one preferred embodiment, the metal containing precursor is comprised of the formula:
Hf(NRR′)₄
where R and R″ are each independently=C1-C6 linear, branched, or cyclic carbons, or substituted carbon groups; and R and R′ may equal, or R and R′ may be different;
ammonia (NH₃) is employed as the nitrogen containing precursor, and the method is carried out at temperature in the range of approximately 100° C. to 400° C. to form a hafnium nitride (HfN) film. Preferably, the hafnium containing source is comprised of tetrakis(ethylmethyamino) hafnium (TEMA-Hf).

Suitable nitridating precursors include ammonia, deuterated ammonia, ¹⁵N-ammonia, amines or amides, hydrazines, alkyl hydrazines, nitrogen gas, nitric oxide, nitrous oxide, nitrogen radicals, N-oxides, ND₃, and mixtures thereof.

If desired, the metal nitride film may be further processed to form an oxynitride or silicate film by oxidizing the film in step 108. Oxidation of the metal nitride film may be carried out with oxidizing sources such as ozone, oxygen, signlet oxygen, triplet oxygen, water, peroxides, air, nitrous oxide, nitric oxide, H₂O₂, and mixtures thereof. In a preferred embodiment where the metal nitride film is comprised of hafnium nitride, the film is oxidized by exposure to ozone at a temperature of less than approximately 400° C. to form hafnium oxynitride (HfON). This exemplary embodiment may be summarized by the following sequence, where “p/p” means separate pulse and purge steps. The term “pulse” is used in the industry to refer to the conveying of the precursor to the process chamber.

$${Hf ( {NR}_{2} )}_{4} p \text{/} p + {NH}_{3} p \text{/} p {\to }_{200 - 400 ° C .} HfN {\to }_{oxidation {O}_{3}} HfON \qquad eq ( 1 )$$

Alternatively, a metal oxynitride film may be formed by in-situ oxidation of oxygen during the ALD cycles by conveying an oxygen containing precursor as a pulse. Namely, eq(2) below represents one ALD cycle to form HfON. In a preferred embodiment, the oxygen containing precursor is comprised of ozone. This exemplary embodiment may be summarized by the following sequence:

$${Hf ( {NR}_{2} )}_{4} p \text{/} p + {NH}_{3} p \text{/} p + {O}_{3} p \text{/} p {\to }_{200 - 400 ° C .} HfON \qquad eq ( 2 )$$

Of particular advantage both embodiments of the present invention provide for incorporating nitrogen into the high-k dielectric film at temperatures much lower than conventional nitridation techniques, such as post deposition annealing in ammonia which is carried out at temperatures of approximately 700 to 800° C. and higher. Furthermore, post deposition annealing in ammonia typically requires a process time of up to 5 minutes or more which is considerably long. In contrast, incorporating nitrogen in the dielectric film by the method of the present invention may be carried out in less than half that time.

In another aspect of the present invention, nitridated metal-silicon and metal-silicon-oxygen films are formed. Referring to FIG. 2, one embodiment of a method according to the present invention is illustrated. Metal and silicon containing precursor gases are conveyed as a pulse at step 200 to a process chamber housing one or more semiconductor substrates. Preferably, the metal and silicon precursors are conveyed together or “co-injected” to the process chamber in a single pulse step, instead of being separately pulsed. This method of pulsing two different precursors in one pulse step is described in detail in pending U.S. patent application Ser. No. 10/869,770 filed on Jun. 15, 2004, which is a CIP application of U.S. patent application Ser. No. 10/829,781 filed on Apr. 21, 2204, the disclosures of both of which are hereby incorporated by reference in their entirety.

The metal and silicon containing precursors are chemisorbed on the surface of the one or more substrates according to known atomic layer deposition principles to form a metal-silicon mono-layers. The process chamber is purged at step 202 to remove the excess precursors. Next, a nitrogen containing precursor gas is conveyed to the process chamber as a pulse at step 204. Nitrogen is chemisorbed on the surface of the substrate to form one or more metal-silicon-nitrogen films or layers on the substrate. The process chamber is then purged at step 206 to remove any remaining nitrogen containing precursors.

In one preferred embodiment, the metal containing precursor is comprised of the formula:
Hf(NRR′)₄
where R and R′ are each independently=C1-C6 linear, branched, or cyclic carbons, or substituted carbon groups; and R may equal R′, or R and R′ may be different;
the silicon containing precursor is comprised of the formula:
   Si(NRR′)₄
   where R and R′ are each independently=C1-C6 linear, branched, or cyclic carbons, or substituted carbon groups; and R may equal R′, or R and R′ may be different;
ammonia (NH₃) is employed as the nitrogen containing precursor, and the method is carried out at temperature in the range of approximately 100° C. to 400° C. to form a hafnium silicon nitride (HfSiN) film. Preferably dialkyl amide ligands are the same between the Hf and Si complexes. In one preferred embodiment, the hafnium containing precursor is comprised of tetrakis(ethylmethyamino) hafnium (TEMA-Hf) and the silicon containing precursor is comprised of tetrakis(ethylmethylamino) silicon (TEMA-Si).

Suitable nitridating precursors include ammonia, deuterated ammonia, ¹⁵N-ammonia, amines or amides, hydrazines, alkyl hydrazines, nitrogen gas, nitric oxide, nitrous oxide, nitrogen radicals, N-oxides, ND₃, and mixtures thereof.

The silicon and hafnium precursors are typically in liquid form and are vaporized to form gases for processing. Preferably the precursors are vaporized using one or more bubbler system as described in more detail in U.S. patent application Ser. No. 10/869,770 filed on Jun. 15, 2004 which s incorporated herein by reference.

The metal-silicon-nitride film may be further processed to form an oxynitride film by oxidizing the film as in step 208. Oxidation of the metal-silicon-nitride film may be carried out with suitable oxidizing sources such as ozone, oxygen, signlet oxygen, triplet oxygen, water, peroxides, air, nitrous oxide, nitric oxide, H₂O₂, and mixtures thereof. In a preferred embodiment, the film is oxidized by exposure to ozone at a temperature of less than approximately 400° C. to form hafnium silicon oxynitride (HfSiON). This exemplary embodiment of the method may be summarized by the following sequence, where “p/p” means separate pulse and purge steps.

$$[ {Hf ( {NR}_{2}^{′} )}_{4} + {Si ( {NR}_{2}^{′} )}_{4} ] p \text{/} p + {NH}_{3} p \text{/} p {\to }_{200 - 400 ° C .} HfSiN {\to }_{oxidation {O}_{3}} HfSiON \qquad eq ( 3 )$$

Alternatively, a metal-silicon oxynitride film may be formed by in-situ oxidation during the ALD process by conveying an oxygen containing precursor as a pulse, instead of by post-deposition oxidation of the film. In a preferred embodiment, the oxygen containing precursor is comprised of ozone. This exemplary embodiment may be summarized by the following sequence:

$$[ {Hf ( {NR}_{2}^{″} )}_{4} + {Si ( {NR}_{2}^{″} )}_{4} ] p \text{/} p + {NH}_{3} p \text{/} p + {O}_{3} p \text{/} p {\to }_{200 - 400 ° C .} HfSiON \qquad eq ( 4 )$$

In another aspect of the present invention, a method of forming a nano-laminate film is provided. As used herein, the term nano-laminate refers to a device having a multi-layer stack of films, such as alternating layers of HfN/HfO₂ or HfSiN/HfSiO, and the like. In general, the individual layers are formed as described above. In an exemplary embodiment of the present invention, a nano-laminate film is formed according to the following cycle:
{(Hf(NR₂)₄p/p or [Hf(NR₂)₄+Si(NR₂)₄]p/p)+NH₃p/p} repeat x times+{(Hf(NR₂)₄p/p or [Hf(NR₂)₄+Si(NR₂)₄]p/p)+O₃p/p} repeat y times; and repeat the cycle until the desired film thickness is achieved. eq(5)

In another aspect of the present invention, a method for the deposition of a multi-layer material wherein nitrogen is incorporated into the material for use as the gate dielectric layer in a semiconductor device is provided. The first step in the present invention is to deposit a first layer having a first composition using a first set of process conditions on a semiconductor substrate.

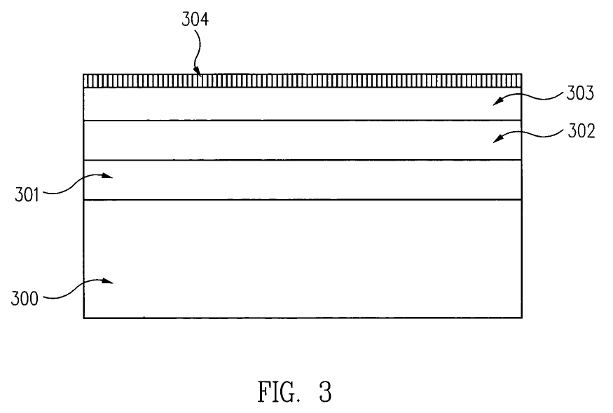

The composition of the first layer is chosen to promote desired properties of high mobility and a stable interface against the semiconductor surface. Referring to FIG. 3 a first layer 301 is formed atop a semiconductor substrate 300. An example of a class of materials that may be used for the first layer comprises metal silicates. These materials have a metal-silicon-oxygen composition. The metal may comprise any one or combination of Ti, Zr, Hf, Ta, W, Mo, Ni, Cr, Y, La, C, Nb, Zn, Al, Sn, Ce, Pr, Sm, Eu, Tb, Dy, Ho, Er, Tm, Yb, Lu or the like. Preferably, the metal is Hf. The composition of the first layer is silicon rich, meaning the silicon concentration is greater than the metal concentration. This has the affect of making the metal-silicon-oxygen material act more like SiO₂ with an added concentration of the metal oxide. Therefore, the material and dielectric properties of the first layer will be more similar to the well-known SiO₂ used as a gate dielectric layer. Consequently, the desired properties of high mobility (faster transistor speed) and a stable interface with respect to the semiconductor surface will be preserved. The first layer should be as thin as possible because Si-rich silicates generally have a lower dielectric constant.

Preferably the first layer 301 is comprised of hafnium silicate (HfxSiyOz), where x<y. This film may be deposited by any means such as atomic layer deposition (ALD), chemical vapor deposition (CVD), metal-organic chemical vapor deposition (MOCVD), physical vapor deposition (PVD), jet vapor deposition, aerosol pyrolysis, sol-gel coating, spin-on metal-organic decomposition technique and the like. The preferred method of deposition is ALD.

The hafnium precursor may comprise any one or combination hafnium dialkyl amides, hafnium alkoxides, hafnium dieketonates, hafnium chloride (HfCl₄), and the like, most preferably tetrakis (ethylmethylamino) hafnium (TEMA-Hf). The silicon precursor may comprise any one or combination of aminosilane, silicon alkoxides, silicon dialkyl amides, silane, silicon chlorides, tetramethyldisiloxane (TMDSO) and the like, most preferably tetrakis(ethylmethylamino) silicon (TEMA-Si). Inert gases, such as He, Ar, N₂ or mixtures thereof, can be used as a carrier gas and a diluent for the precursors. The oxygen source may comprise any one or combination of ozone (O₃), oxygen (O₂), atomic oxygen, water, nitric oxide (NO), nitrous oxide (N₂O), peroxide (H₂O₂), alcohol, and the like, most preferably O₃. In an exemplary embodiment the first layer 301 with a composition of Hf(1-x)SixO₂ where x=0 to 0.5 is deposited by ALD from TEMA-Hf, TEMA-Si, and O₃ at a temperature range of 100 to 500° C., a pressure range of 0.01 to 10 Torr, and flow rates of 1 to 5,000 sccm of TEMA-Hf, 1 to 5,000 sccm of TEMA-Si, and 1 to 10,000 sccm of O3. The resulting film has a dielectric constant of 4 to −10 and a mobility of >70% relative to pure SiO₂ for a CMOS device.

To form the multiplayer gate device a second layer 302 having a second composition using a second set of process conditions is formed atop the first layer 301. The composition of the second layer is chosen to promote a desired high dielectric constant. An example of a class of materials that may be used for the second layer comprises metal oxides or metal silicates. These materials have a metal-oxygen or metal-silicon-oxygen composition. The metal may comprise any one or combination of Ti, Zr, Hf, Ta, W, Mo, Ni, Cr, Y, La, C, Nb, Zn, Al, Sn, Ce, Pr, Sm, Eu, Th, Dy, Ho, Er, Tm, Yb, Lu or the like. Preferably, the metal is hafnium (Hf). The composition of the second layer for the case of the metal silicates is metal rich, meaning the silicon concentration is less than the metal concentration. This has the affect of making the metal-silicon-oxygen material act more like metal oxide with an added concentration of the SiO₂. Therefore, the material and dielectric properties of the second layer will be more similar to the well-known metal oxides used as a dielectric layer and have a higher “k-value”. Consequently, the desired properties of high dielectric constant will be preserved. The second layer thickness should be selected to meet the desired dielectric properties of the gate dielectric layer.

In a preferred embodiment second layer 302 is formed by deposition of a layer of hafnium oxide (HfO₂) or hafnium silicate (HfxSiyOz), where x>y. This film may be deposited by any means such as atomic layer deposition (ALD), chemical vapor deposition (CVD), metal-organic chemical vapor deposition (MOCVD), physical vapor deposition (PVD) and the like. The preferred deposition method is ALD.

The hafnium precursor may comprise any one or combination of hafnium dialkyl amides, hafnium alkoxides, hafnium dieketonates, hafnium chloride (HfCl₄), and the like, most preferably tetrakis(ethylmethylamino) hafnium (TEMA-Hf). The silicon precursor may comprise any one or combination of aminosilane, silicon alkoxides, silicon dialkyl amides, silane, silicon chlorides, tetramethyldisiloxane (TMDSO) and the like, most preferably tetrakis(ethylmethylamino) silicon (TEMA-Si). The oxygen precursor may comprise any one or combination of ozone (O₃), oxygen (O₂), atomic oxygen, water (H₂O), nitric oxide (NO), nitrous oxide (N₂O), peroxide (H₂O₂), alcohol, and the like, most preferably O₃. In the exemplary embodiment HfO₂ is deposited by ALD from TEMA-Hf and O₃ in separate pulse and purge steps, at a temperature range of 100 to 400 C, a pressure range of 0.01 to 10 Torr, and flow rates of 1 to 5,000 sccm of TEMA-Hf, and 1 to 10,000 sccm of O₃. The resulting film has a dielectric constant of 15 to 25. A second layer with a composition of HfxSi(1-x)O₂ where x=0.5 to 1 is deposited by ALD from TEMA-Hf and TEMA-Si together in one pulse and purge step, followed by a separate pulse and purge step using O₃, at a temperature range of 100 to 500° C., a pressure range of 0.01-10 Torr, and flow rates of 1 to 5,000 sccm of TEMA-Hf, 1 to 5,000 sccm of TEMA-Si, and 1 to 10,000 sccm of O₃. The resulting film has a dielectric constant of 10 to 25. In each case, the second layer 302 is deposited sequentially and “in-situ” in the same process chamber as the first layer 301. This has the benefit of faster cycle time and lower cost of ownership for the manufacture of the semiconductor device.

The third step provides for depositing a third layer 303 having a third composition using a third set of process conditions atop the second layer 302 and then incorporating nitrogen into the third layer according to the present invention. The composition of the third layer is chosen to promote desired properties of acting as an effective diffusion barrier to boron. An example of a class of materials that may be used for the third layer comprises: metal oxynitrides or metal-silicon-oxynitrides. These materials have a metal-oxygen-nitrogen or metal-silicon-oxygen-nitrogen composition. The metal may comprise any one or combination of Ti, Zr, Hf, Ta, W, Mo, Ni, Cr, Y, La, C, Nb, Zn, Al, Sn, Ce, Pr, Sm, Eu, Th, Dy, Ho, Er, Tm, Yb, Lu or the like. Preferably the metal is hafnium (Hf). The third layer thickness should be selected to meet the desired dielectric properties of the gate dielectric layer.

Preferably, the third layer 303 is formed by ALD deposition of a layer of hafnium nitride (HfN) or hafnium-silicon-nitrogen (HfxSiyNz), either sequentially or by co-injection as described above, followed by oxidation of the HfN or HfxSiyNz film to form a third layer 303 comprised of HfON or HfSiON. The hafnium precursor may comprise any one or combination of hafnium dialkyl amides, hafnium alkoxides, hafnium dieketonates, hafnium chloride (HfCl4), and the like, most preferably tetrakis(ethylmethylamino) hafnium (TEMA-Hf). The silicon precursor may comprise any one or combination of aminosilane, silicon alkoxides, silicon dialkyl amides, silane, silicon chlorides, tetramethyldisiloxane (TMDSO) and the like, most preferably tetrakis(ethylmethylamino) silicon (TEMA-Si). The nitrogen precursor may comprise any one or combination of ammonia (NH₃), nitrogen (N₂)—ND₃, atomic nitrogen, hydrazine (N₂H₂), and the like, most preferably NH₃. In one example, HfN is deposited by ALD from TEMA-Hf, and NH₃ in separate pulse and purge steps, at a temperature range of 100 to 500° C., a pressure range of 0.01 to 10 Torr, and flow rates of 1 to 5,000 sccm of TEMA-Hf, and 1 to 10,000 sccm of NH₃. Alternatively, third layer 303 with a composition of HfxSi(1-x)N₂ where x=0 to 1 is deposited by ALD from TEMA-Hf and TEMA-Si in one pulse and purge step, followed by a pulse and purge step using NH₃ at temperature range of 100 to 500° C., a pressure range of 0.01-10 Torr, and flow rates of 1 to 500 sccm of TEMA-Hf, 1 to 5,000 sccm of TEMA-Si, and 1 to 10,000 sccm of NH₃. In each case, the third layer 303 is deposited sequentially and “in-situ” in the same process chamber as the first and second layers. This has the benefit of faster cycletime and lower cost of ownership for the manufacture of the semiconductor device.

Optionally, third layer 303 is then reacted with an oxygen source or precursor to form a metal-oxygen-nitrogen or metal-silicon-oxygen-nitrogen material. The reacted layer is shown as layer 304 in FIG. 3. The inclusion of the nitrogen in the composition has the affect of blocking the diffusion paths for boron through the dielectric, thus lowering the effective diffusivity of boron through the gate dielectric layer. This is important for the long-term performance and reliability of the semiconductor device. This method provides thickness control of the nitrided high-k layers, and therefore, the depth of nitrogen from the surface into the multilayer stack can be controlled. In order to maintain high mobility of CMOS device, it is preferred not to have nitrogen atoms at the interface between Si substrates and high-k stacks.

The reaction with oxygen may be carried out by oxidation of the third layer 303 as described above in sequences eq(1) and eq(3), or alternatively by ALD employing an oxygen precursor during the film forming step of the third layer as described above in sequences eq(2) and eq(4).

The oxygen source may comprise any one or combination of ozone (O₃), oxygen (O₂), water, atomic oxygen, peroxide (H₂O₂), nitrous oxide (N₂O), nitric oxide (NO) and the like.

When employing post oxidation instead of oxidizing the layer during the ALD process, the high reactivity of O₃ allows the oxidation reaction to proceed at low temperatures. However, the post oxidation reaction may require a suitable energy source in some cases. The suitable energy source may comprise any one or combination of thermal, direct plasma, remote plasma, downstream plasma, ultraviolet photon energy or the like, most preferably remote plasma. The oxygen source and energy source (if required) are combined to introduce an oxygen concentration between 0 atomic percent and 66 atomic percent within the alternate third layer. This method allows nitrogen to be controlled in the third, or “top” layer of the multi-layer material. This preserves the desired boron blocking properties of the reacted alternative third layer while also preserving the desired dielectric properties of the second layer and the mobility and stability properties of the first layer. For oxidation of a hafnium-nitrogen or hafnium-silicon-nitrogen compound used as the third layer, the third layer is treated with ozone at a temperature range of 25 to 500° C., a pressure range of 0.01-10 Torr, and a flow rate of 1 to −10,000 sccm of ozone.

For the preferred case of using ozone as the oxygen species during ALD, an alternate energy source is not required. In this case, the third layer 303 may either be treated with the oxygen precursor sequentially and “in-situ” in the same process chamber as the first and second layers. This has the benefit of faster cycletime and lower cost of ownership for the manufacture of the semiconductor device.

### Experimental

A number of experiments were conducted and are presented herein for illustrations purposes only, and are not meant to limit the scope of the invention in any way.

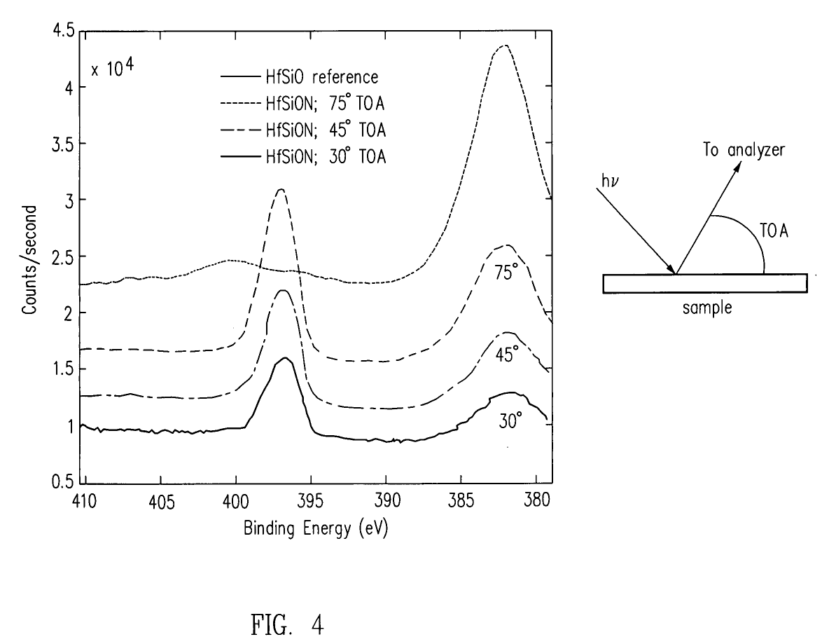

FIG. 4 shows the X-ray Photoelectron Spectroscopy (XPS) spectra for nitrogen 1 s and hafnium 4p3/2 regions for an HfSiOx film nitridated with ammonia in a post-deposition annealing step at high temperature of approximately 800° C. for duration of five minutes. Relative to HfSiOx, the XPS spectra of an HfSiON film at various take-off angles (TOA) reveal the presence of nitrogen in the film. Relative to an HfSiO reference (also shown in FIG. 4), the presence of the nitrogen peak near 400 eV indicates the incorporation of nitrogen into the HfSiO layer. Measurements at various take-off angles (TOA) detect the presence of HfSiON not only at the surface of the dielectric, but also deep within the film.

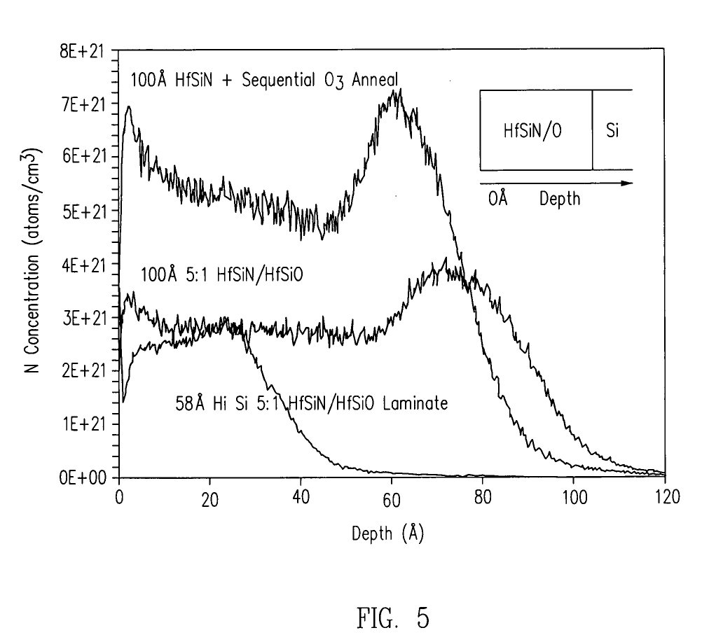

Experiments were conducted to form a number of films according to various embodiments of the present invention. Process conditions for a number of experiments are summarized in Table 1 below. The process conditions in Table 1 correspond to the various film data presented in the FIGS. 5 though 8.

TABLE 1

| | | Dep | TemaHf | TemaSi | | Metal | Metal | NH3 | NH3 | Metal | Metal | O3 | O3 |
|---|---|---|---|---|---|---|---|---|---|---|---|---|---|
| | | Temp | Ar | Ar | O3 Conc | pulse | purge | pulse | purge | pulse | purge | pulse | purge |
| FIG. | Film | (C.) | (sccm) | (sccm) | (g/m3) | (s) | (s) | (s) | (s) | (s) | (s) | (s) | (s) |
| 5 | 5:1 (HfSiN + 0.5 s Sequential O3 | 350 | 450 | 50 | 100 | 1 | 1.5 | 2 | 5 | | | 0.5 | 10 |
| | Anneal) | | | | | | | | | | | | |
| 5 | 5:1 HfSiN/HfSiO laminate | 350 | 350 | 50 | 250 | 1 | 1.5 | 2 | 5 | 1 | 1.5 | 1.5 | 10 |
| 5 | 5:1 HfSiN/HfSiO laminate with | 350 | 200 | 200 | 250 | 1 | 1.5 | 2 | 5 | 1 | 1.5 | 1.5 | 10 |
| | higher Si content | | | | | | | | | | | | |
| 6 | 20 A HfSiN/in situ PDA 10 s 1 | 330 | 450 | 50 | 200 | 1 | 5 | 2 | 5 | | | | |
| | Torr O3 + 30 A HfO2 | | | | | | | | | | | | |
| 6 | 20 A 5:1 (HfSiN + Sequential O3 | 330 | 450 | 50 | 200 | 1 | 5 | 2 | 5 | | | 2 | 10 |
| | anneal) + 30 A HfO2 | | | | | | | | | | | | |
| 6 | 20 A 5:1 HfSiN/HfSiO Laminate + | 330 | 350 | 50 | 250 | 1 | 5 | 2 | 5 | 1 | 1.5 | 1.5 | 10 |
| | 30 A HfO2 | | | | | | | | | | | | |
| 7 | HfSiN, PDA 1 min in situ 1 Torr | 300 | 450 | 50 | 200 | 1 | 5 | 2 | 5 | | | | |
| | O3 anneal | | | | | | | | | | | | |
| 8 | 5:1 (HfN + 2 s Sequential O3 | 350 | 450 | 0 | 200 | 1 | 5 | 2 | 5 | | | 2 | 10 |
| | Anneal) | | | | | | | | | | | | |
| | 5:1 (HfSiN + 2 s Sequential O3 | 350 | 450 | 50 | 200 | 1 | 1.5 | 2 | 5 | | | 2 | 10 |
| | Anneal) | | | | | | | | | | | | |
| 8 | 5:1 HfN/HfO Laminate | 350 | 450 | 0 | 180 | 1 | 1.5 | 2 | 5 | 1 | 1.5 | 1 | 10 |
| 8 | 5:1 HfSiN/HfSiO Laminate | 350 | 350 | 50 | 250 | 1 | 1.5 | 2 | 5 | 1 | 1.5 | 1 | 10 |

Where: PDA = post deposition anneal
All processes used 1 Torr process pressure.
O₂/O₃ flow = 450 sccm except for HfSiO film in FIG. 4.
NH₃ flow = 450 sccm
Dep Temp (° C.) refers to the temperature at which the ALD process is carried out and is specifically the temperature of the wafer or substrate

FIG. 5 illustrates SIMS depth profiles showing nitrogen concentration (atomes/cm³) as a function of film depth for high-k dielectric films formed according to various embodiments of the present invention. The compositional profile of a HfSiNO layer formed atop a silicon substrate is shown with a depth of 0 Å representing the top of the HfSiNO film which is farthest away from the silicon substrate. The SIMS depth profile is shown for HfSiNO films formed according to the sequences show in eq(3) and eq(4) and these results are compared against a laminate film The films were deposited by atomic layer deposition at a wafer temperature of 350° C. and a pressure of 1 Torr. The laminate films were formed with 5:1 sequences meaning five sequences of HfSiN for every one sequence of HfSiO. The “in-sequence” O₃ anneal film (meaning ozone is used during the ALD cycle) was formed with 5 sequences of HfSiN for each O₃ pulse.

For each of the curves illustrated in FIG. 5, the HfSiN ALD pulse step comprised 1 second TEMAHf/TEMASi pulse, followed by 1.5 second purge, 2 second NH₃ pulse, and 5 second purge. For the two laminate films, the HfSiO ALD pulse times were: 1/1.5/1.5/10 seconds (chemical pulse/purge/O₃ pulse/purge, respectively). The film formed with sequential O₃ anneal was carried out with: O₃ pulse 0.5 seconds followed by 10 second purge. These values and other process details (TEMAHF, TEMASi carrier Ar flows, O₃ concentrations) are summarized in Table 1.

As shown in FIG. 5, nitrogen is present throughout the depth of the HfSiNO film until the interfacial layer of the silicon substrate is reached.

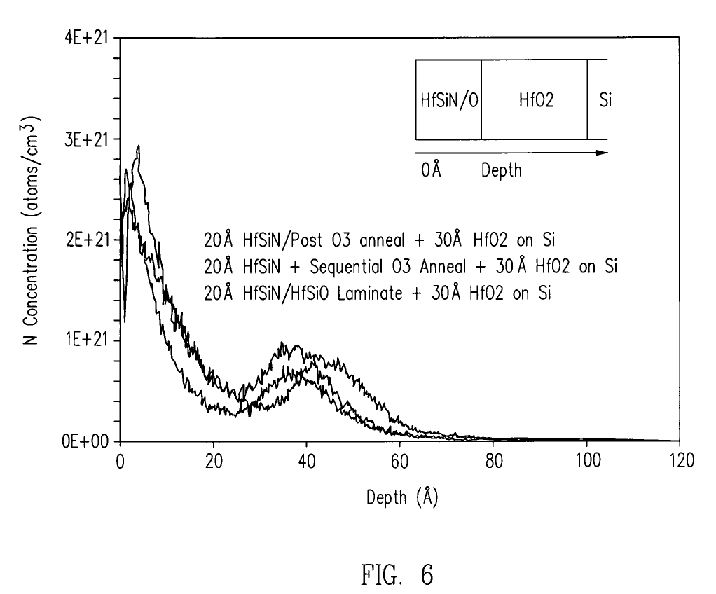

FIG. 6 depicts SIMS depth profiles illustrating nitrogen concentration (atoms/cm³) as a function of film depth for high-k dielectric gate stack formed according to other various embodiments of the present invention. In this instance, a gate device is shown comprising a silicon substrate having an HfO₂ layer formed atop the substrate, and a layer of HfSiNO formed atop the HfO₂ layer. Each of the films was formed according to the process conditions shown in Table 1 for FIG. 6. In such a gate device it is beneficial to incorporate nitrogen in the top layer, away from the silicon substrate interface as nitrogen may deteriorate mobility is a CMOS device when close to the interface with the substrate. Of particular advantage, as shown in FIG. 6 the method of the present invention promotes the highest concentration of nitrogen in the top layer, and allows for control of the placement of nitrogen within the device.

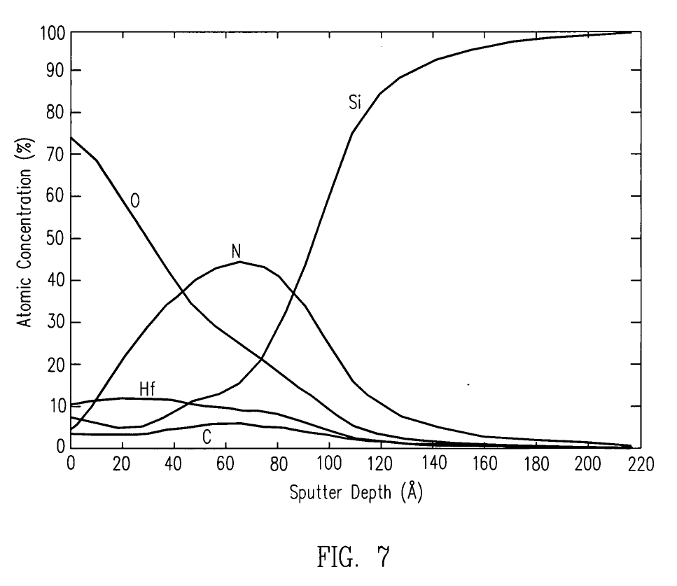

FIG. 7 is a graph showing atomic concentration (atomic %) of various constituents as a function of sputter depth present in post ozone annealed (i.e. oxidized) HfSiN films formed according to sequence eq(3) of the present invention. Each of the films was formed according to the process conditions shown in Table 1 for FIG. 7 In particular, the results confirm the presence of nitrogen in the bulk region of the film. Oxygen is most prevalent at the top of the film, showing that nitrogen is easily substituted by oxygen in the post ozone annealing process.

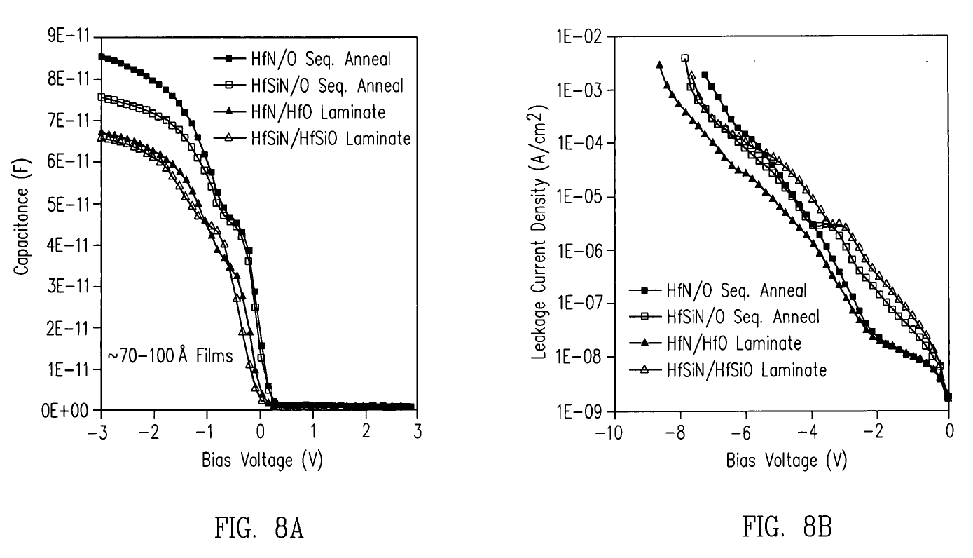

FIGS. 8A and 8B illustrate electrical performance of capacitance and leakage current density, respectively, as a function of bias voltage for films formed according to various embodiments of the present invention. The process conditions utilized to form the films are summarized in Table 1 shown in the FIG. 8 rows. Films formed by the method of the present invention exhibit desirable electrical characteristics.

As described above, a method for depositing a multi-layer gate dielectric material that maintains the desirable properties of SiO₂ and overcomes the problems is provided. The foregoing description of specific embodiments of the invention has been presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and their equivalents.

1. A method of forming a high-k dielectric film on one or more substrates in a process chamber, comprising the steps of:
conducting one or more atomic layer deposition cycles, each cycle carried out at a temperature of approximately 500° C. or less and comprising:
(a) conveying a metal containing precursor to the process chamber to form a layer or layers of metal atoms on the surface of the substrate;
(b) removing excess metal containing precursor from the process chamber
(c) conveying a nitrogen containing precursor to the process chamber wherein nitrogen interacts with the layer of metal atoms to form a metal-nitrogen film on the substrate; and
(d) removing excess nitrogen containing precursor from the process chamber;
followed by oxidizing the metal-nitrogen film to form a high-k dielectric film on the surface of the substrate.

2. The method of claim 1 wherein the one or more atomic layer deposition cycles are carried out at a temperature in the range of approximately 25° C. to 500° C.

3. The method of claim 1 wherein the one or more atomic layer deposition cycles are carried out at a temperature in the range of approximately 100° C. to 400° C.

4. The method of claim 1 wherein the oxidizing step is carried out at the same temperature as the atomic layer deposition cycles.

5. The method of claim 1 wherein the oxidizing step is carried out in the same process chamber as the atomic layer deposition cycles.

6. The method of claim 1 wherein the one or more atomic layer deposition cycles further comprises:
conveying a metal containing precursor and a silicon containing precursor together to the process chamber to form a layer or layers of metal and silicon atoms on the surface of the substrate.

7. The method of claim 1 wherein said metal containing precursor is comprised of the formula:
Hf(NRR′)₄
where R and R′ are each independently=C1-C6 linear, branched, or cyclic carbons, or substituted carbon groups, and where R=R′, or R and R′ are different.

8. The method of claim 1 wherein said metal containing precursor is tetrakis(ethylmethlyamino) hafnium

9. The method of claim 1 wherein said nitrogen containing precursor is comprised of: ammonia, deuterated ammonia, 15N-ammonia, amines or amides, hydrazines, alkyl hydrazines, nitrogen gas, nitric oxide, nitrous oxide, nitrogen radicals, N-oxides, ND₃, and mixtures thereof.

10. The method of claim 6 wherein said silicon containing precursor is comprised of the formula:
Si(NRR′)₄
where R and R′ are each independently=C1-C6 linear, branched, or cyclic carbons, or substituted carbon groups, and where R=R′, or R and R′ are different.

11. The method of claim 6 wherein said silicon containing precursor is tetrakis(ethylmethlyamino) silicon.

12. The method of claim 1 wherein the process chamber is adapted to process a plurality of substrates.

13. A method of forming a high-k dielectric film on one or more substrates in a process chamber, comprising the steps of:
conducting one or more atomic layer deposition cycles, each cycle carried out at a temperature of approximately 500° C. or less and comprising:
(a) conveying a metal containing precursor to the process chamber to form one or more layers of metal atoms on the surface of the substrate;
(b) removing excess metal containing precursor from the process chamber
(c) conveying a nitrogen containing precursor to the process chamber wherein nitrogen interacts with the one or more layers of metal atoms to form a metal-nitrogen film on the substrate;
(d) removing excess nitrogen containing precursor from the process chamber; and
(e) conveying an oxygen containing precursor to the process chamber wherein oxygen oxidizes the metal-nitrogen film to form a high-k dielectric film on the surface of the substrate; and
(f) removing excess oxygen containing reactant from the process chamber.

14. The method of claim 13 wherein the one or more atomic layer deposition cycles are carried out at a temperature in the range of approximately 25° C. to 500° C.

15. The method of claim 13 wherein the one or more atomic layer deposition cycles are carried out at a temperature in the range of approximately 100° C. to 400° C.

16. The method of claim 13 wherein the oxygen containing precursor is comprised of ozone.

17. The method of claim 13 wherein the one or more atomic layer deposition cycles further comprises:
conveying a metal containing precursor and a silicon containing precursor together to the process chamber to form one or more layers of metal and silicon atoms on the surface of the substrate.

18. The method of claim 13 wherein said metal containing precursor is comprised of the formula:
Hf(NRR′)₄
where R and R′ are each independently=C1 to C6 linear, branched, or cyclic carbons, or substituted carbon groups, and where R=R′ or R and R′ are different.

19. The method of claim 13 wherein said metal containing precursor is tetrakis(ethylmethlyamino) hafnium

20. The method of claim 13 wherein said nitrogen containing precursor is comprised of: ammonia, deuterated ammonia, 15N-ammonia, amines or amides, hydrazines, alkyl hydrazines, nitrogen gas, nitric oxide, nitrous oxide, nitrogen radicals, N-oxides, ND₃, and mixtures thereof.

21. The method of claim 17 wherein said silicon containing precursor is comprised of the formula:
Si(NRR′)₄
where R and R′ are each independently=C1-C6 linear, branched, or cyclic carbons, or substituted carbon groups, and where R=R′, or R and R′ are different.

22. The method of claim 17 wherein said silicon containing precursor is tetrakis(ethylmethlyamino) silicon.

23. The method of claim 13 wherein the process chamber is adapted to process a plurality of substrates.

24. The method of claim 13 wherein the atomic layer deposition cycles are repeated to form a nano laminate high-k dielectric film.

25. A method of forming a high-k dielectric film on one or more substrates in a process chamber, comprising the steps of:
conducting one or more atomic layer deposition cycles, each cycle carried out at a temperature of approximately 500° C. or less and comprising:
(a) co-injecting a metal containing precursor gas and a silicon containing precursor gas together to the process chamber to form one or more layers of metal and silicon atoms on the surface of the substrate;
(b) removing excess metal containing precursor from the process chamber
(c) conveying a nitrogen containing precursor to the process chamber wherein nitrogen interacts with the one or more layers of metal atoms to form a metal-nitrogen film on the substrate; and
(d) removing excess nitrogen containing precursor from the process chamber;
oxidizing the metal-nitrogen film to form a high-k dielectric film on the surface of the substrate.

26. A method of forming a high-k dielectric film on one or more substrates in a process chamber, comprising the steps of:
conducting one or more atomic layer deposition cycles, each cycle carried out at a temperature of approximately 500° C. or less and comprising:
(a); co-injecting a metal containing precursor gas and a silicon containing precursor gas together to the process chamber to form one or more layers of metal and silicon atoms on the surface of the substrate
(b) removing excess metal containing precursor from the process chamber
(c) conveying a nitrogen containing precursor to the process chamber wherein nitrogen interacts with the one or more layers of metal atoms to form a metal-nitrogen film on the substrate;
(d) removing excess metal containing precursor form the process chamber;
(e) conveying an oxygen containing precursor to the process chamber wherein oxygen oxidizes the metal-nitrogen film to form a high-k dielectric film on the surface of the substrate; and
(f) removing excess oxygen containing precursor from the process chamber.

27. A method of depositing a multi-layer material on a semiconductor wafer to form a gate dielectric material characterized in that: a first layer having a first composition is deposited under a first set of conditions on a substrate followed by the deposition of a second layer having a second composition, said second layer deposition carried out under a second set of conditions, followed by the deposition of a third layer having a third composition, said third layer deposition carried out under a third set of conditions, and followed by the reaction of the third layer with a reactive gas to alter the composition of said third layer to form a material with a fourth composition.

28. The method of claim 27 wherein the first layer is a metal-silicon-oxygen compound and the concentration of silicon is greater than the concentration of said metal.

29. The method of claim 27 wherein the second layer is a metal-oxygen compound.

30. The method of claim 27 wherein the second layer is a metal-silicon-oxygen compound and the concentration of silicon is less than the concentration of said metal.

31. The method of claim 27 wherein the third layer is a metal-nitrogen compound.

32. The method of claim 27 wherein the third layer is a metal-silicon-nitrogen compound.

33. The method of claim 31 wherein said third layer is reacted with an oxygen species to form a metal-oxygen-nitrogen compound as said fourth composition.

34. The method of claim 32 wherein said third layer is reacted with an oxygen species to form a metal-silicon-oxygen-nitrogen compound as said fourth composition.

35. The method of claim 27 wherein the first layer is a metal-silicon-oxygen compound and the concentration of silicon is greater than the concentration of said metal, and wherein the second layer is a metal-oxygen compound and the concentration of silicon is less than the concentration of said metal, and the third layer a metal-nitrogen compound, and said third layer is reacted with an oxygen species to form a fourth metal-nitrogen-oxygen compound.

36. The method of claim 27 wherein the first layer is a metal-silicon-oxygen compound and the concentration of silicon is greater than the concentration of said metal, and wherein the second layer is a metal-oxygen compound and the concentration of silicon is less than the concentration of said metal, and the third layer a metal-silicon-nitrogen compound, and said third layer is reacted with an oxygen species to form a fourth metal-silicon-nitrogen-oxygen compound.

37. The method of claim 27 wherein the first layer is a metal-silicon-oxygen compound and the concentration of silicon is greater than the concentration of said metal, and wherein the second layer is a metal-silicon-oxygen compound and the concentration of silicon is less than the concentration of said metal, and the third layer a metal-nitrogen compound, and said third layer is reacted with an oxygen species to form a fourth metal-nitrogen-oxygen compound.

38. The method of claim 27 wherein the first layer is a metal-silicon-oxygen compound and the concentration of silicon is greater than the concentration of said metal, and wherein the second layer is a metal-silicon-oxygen compound and the concentration of silicon is less than the concentration of said metal, and the third layer a metal-silicon-nitrogen compound, and said third layer is reacted with an oxygen species to form a fourth metal-silicon-nitrogen-oxygen compound.

39. The method of claim 27 wherein the metal comprises any one or combination of Ti, Zr, Hf, Ta, W, Mo, Ni, Cr, Y, La, C, Nb, Zn, Al, Sn, Ce, Pr, Sm, Eu, Th, Dy, Ho, Er, Tm, Yb, or Lu.

40. The method of claim 27 wherein the metal comprises Hf.

41. The method of claim 27 wherein the silicon is derived from any one or a combination of aminosilane, silicon alkoxides, silicon dialkyl amides, silane, silicon chlorides, or tetramethyldisiloxane (TMDSO), disilane, aminodisilane, or chlorodisilane

42. The method of claim 27 wherein the silicon is derived from tetrakis(ethylmethylamino) silicon (TEMA-Si).

43. The method of claim 40 wherein the hafnium is derived from tetrakis (ethylmethylamino) hafnium (TEMA-Hf).

44. A method of forming a gate dielectric, comprising the steps of:
forming atop of a substrate a first layer comprised of a metal-silicon-oxygen compound and having a silicon rich concentration;
forming a second layer atop the first layer, the second layer comprised of a metal-silicon-oxygen or metal-oxygen compound and having a metal rich concentration;
forming a third layer atop the second layer, the third layer comprised of a metal-nitrogen or metal-silicon-nitrogen compound; and
treating the surface of the third layer with an oxygen containing species to incorporate oxygen into the third layer.

45. A method of forming a high-k dielectric film on one or more substrates in a process chamber, comprising the steps of:
conducting one or more atomic layer deposition cycles, each cycle carried out at a temperature of approximately 500° C. or less and comprising:
(a) conveying a metal containing precursor to the process chamber to form one or more layers of metal atoms on the surface of the substrate;
(b) removing excess metal containing precursor from the process chamber
(c) conveying a nitrogen containing precursor to the process chamber wherein nitrogen interacts with the one or more layers of metal atoms to form a metal-nitrogen film on the substrate;
(d) removing excess nitrogen containing precursor from the process chamber;
(e) conveying a metal containing precursor to the process chamber to form a layer or layers of metal atoms on the surface of the substrate;
(f) conveying an oxygen containing precursor to the process chamber wherein oxygen oxidizes the metal-nitrogen film to form a high-k dielectric film on the surface of the substrate; and
(g) removing excess oxygen containing reactant from the process chamber.
